(19) United States
(12) Patent Application Publication
(10) Pub. No.: US 2025/0022799 A1
(43) Pub. Date: Jan. 16, 2025

(54) SEMICONDUCTOR PACKAGE AND FABRICATING METHOD THEREOF

(71) Applicant: SAMSUNG ELECTRONICS CO., LTD., Suwon-si (KR)

(72) Inventors: Yong Jin Park, Suwon-si (KR); Ji Hwan Hwang, Suwon-si (KR)

(21) Appl. No.: 18/748,488

(22) Filed: Jun. 20, 2024

(30) Foreign Application Priority Data
Jul. 13, 2023 (KR) 10-2023-0090958

(51) Int. Cl. H01L 23/528; H01L 21/3105; H01L 23/00; H01L 23/48; H01L 25/18; H10B 80/00

(52) U.S. Cl. CPC H01L 23/5283; H01L 21/31051; H01L 23/481; H01L 24/16; H01L 24/32; H01L 24/73; H01L 24/83; H10B 80/00; H01L 25/18; H01L 2224/16145; H01L 2224/32225; H01L 2224/73204; H01L 2224/83203; H01L 2924/1436; H01L 2924/1815

(57) ABSTRACT

Semiconductor package and fabricating method thereof are provided. Semiconductor package comprises a buffer die including a semiconductor substrate having a first surface and a second surface, which face each other, and a passivation layer formed on the first surface, a plurality of core chips stacked on the buffer die, including a first core chip, which is disposed at a lowermost end, among the plurality of core chips, an adhesive layer between the buffer die and the first core chip, and a mold layer surrounding an upper surface of the buffer die and the plurality of core chips, wherein a plurality of recesses recessed inward from an upper surface of the passivation layer are formed on the upper surface of the passivation layer, and the plurality of recesses are formed to surround the first core chip and do not overlap the first core chip horizontally.

### CROSS-REFERENCE TO RELATED APPLICATION

This application claims priority under 35 U.S.C. § 119 to Korean Patent Application No. 10-2023-0090958, filed on Jul. 13, 2023 in the Korean Intellectual Property Office, the content of which in its entirety is herein incorporated by reference.

### BACKGROUND

With lightweight and high performance of electronic devices, miniaturization and high performance have been desired in the field of a semiconductor package. Research and development of semiconductor packages with a structure in which semiconductor chips are stacked in multiple stages have been continuously made to implement miniaturization, light weight, high performance, large capacity and high reliability of the semiconductor packages.

Meanwhile, in a fabricating process of a wafer level package (WLP), a chip stack may be formed by packaging a semiconductor chip, to which a Non-Conductive Film (NCF) is applied, on a wafer and performing thermal compression bonding. At this time, when the NCF for adhering a semiconductor chip placed on a lowest layer of the chip stack to a buffer die or a substrate gets out of an outer region of the semiconductor chip to form a filet, it may cause a defect due to warpage of the substrate.

### BRIEF SUMMARY

The present disclosure relates to a semiconductor package and a fabricating method thereof with reduced defects due to warpage of a substrate.

According to an aspect of the present disclosure, there is a provided semiconductor package comprising a buffer die including a semiconductor substrate having a first surface and a second surface, which face each other, and a passivation layer formed on the first surface, a plurality of core chips stacked on the buffer die, including a first core chip, which is disposed at a lowermost end, among the plurality of core chips, an adhesive layer between the buffer die and the first core chip, and a mold layer surrounding an upper surface of the buffer die and the plurality of core chips, wherein a plurality of recesses recessed inward from an upper surface of the passivation layer are formed on the upper surface of the passivation layer, and the plurality of recesses are formed to surround the first core chip and do not overlap the first core chip in a horizontal viewpoint.

According to an aspect of the present disclosure, there is a provided semiconductor package comprising a package substrate, an interposer on the package substrate, a first semiconductor chip disposed in a first region of the interposer, and a memory device disposed in a second region that does not overlap the first region on the interposer, wherein the memory device includes a buffer die including a semiconductor substrate having a first surface and a second surface, which face each other, and a passivation layer formed on the first surface, a plurality of core chips stacked on the buffer die, including a first core chip, which is disposed on a lowermost end, among the plurality of core chips, an adhesive layer between the buffer die and the first core chip, and a mold layer surrounding an upper surface of the buffer die and the plurality of core chips, a plurality of recesses recessed inward from an upper surface of the passivation layer are formed on the upper surface of the passivation layer, and the plurality of recesses are formed to surround the first core chip and do not overlap the first core chip in a horizontal viewpoint.

According to an aspect of the present disclosure, there is a provided fabricating method of a semiconductor package comprising providing a buffer die including a first semiconductor substrate having a first surface and a second surface, which face each other, and including a through-silicon-via penetrating at least a portion of the buffer die in a vertical direction, forming a passivation layer on a first surface of the first semiconductor substrate, forming a photoresist layer on the passivation layer, disposing a first mask having a first pattern on the buffer die, exposing the buffer die with the first mask interposed therebetween, forming a plurality of recesses, which are recessed inward from an upper surface of the passivation layer, on the upper surface of the passivation layer, by developing the buffer die, removing at least a portion of the passivation layer by a CMP process, forming the photoresist layer on the passivation layer again, disposing a second mask having a second pattern on the buffer die, exposing the buffer die again with the second mask interposed therebetween, forming a backside pad connected to the through-silicon-via by developing the buffer die again, providing a core chip including a second semiconductor substrate having a third surface and a fourth surface, which face each other, and including a bump formed on a lower portion of the core chip, which corresponds to the fourth surface, and an adhesive layer covering the lower portion of the core chip and the bump, stacking the core chip on the buffer die by performing thermal compression bonding between the buffer die and the core chip so that the backside pad of the buffer die and the bump of the core chip are in contact with each other, and forming a mold layer surrounding the upper surface of the passivation layer and the core chip.

### BRIEF DESCRIPTION OF THE DRAWINGS

The above and other aspects and features of the present disclosure will become more apparent by describing in detail exemplary implementations thereof with reference to the attached drawings, in which:

FIG. 1 is an exemplary view illustrating a semiconductor package according to some implementations.

FIG. 2 is an exemplary view illustrating a semiconductor package according to some other implementations.

FIG. 3 is an exemplary top view of FIG. 2.

FIG. 4 is an exemplary cross-sectional view taken along line I-I of FIG. 3.

FIG. 5 is an exemplary cross-sectional view of any one of core chips shown in FIG. 4.

FIGS. 6 to 10 are enlarged views of the region II of FIG. 4.

FIG. 11 is an exemplary view illustrating a semiconductor package according to some other implementations.

FIG. 12 is an exemplary view illustrating a semiconductor package according to some other implementations.

FIGS. 13 and 14 are exemplary views illustrating a semiconductor package according to some implementations.

FIGS. 15 and 16 are exemplary flow charts illustrating a fabricating method of a semiconductor package according to some implementations.

FIGS. 17 to 29 are exemplary views illustrating intermediate steps to describe a fabricating method of a semiconductor package according to some implementations.

FIGS. 30 and 31 are exemplary flow charts illustrating a fabricating method of a semiconductor package according to some other implementations.

FIGS. 32 to 40 are exemplary views illustrating intermediate steps to describe a fabricating method of a semiconductor package according to some other implementations.

### DETAILED DESCRIPTION OF THE DISCLOSURE

Hereinafter, a semiconductor package and a fabricating method thereof according to some implementations will be described with reference to the accompanying drawings.

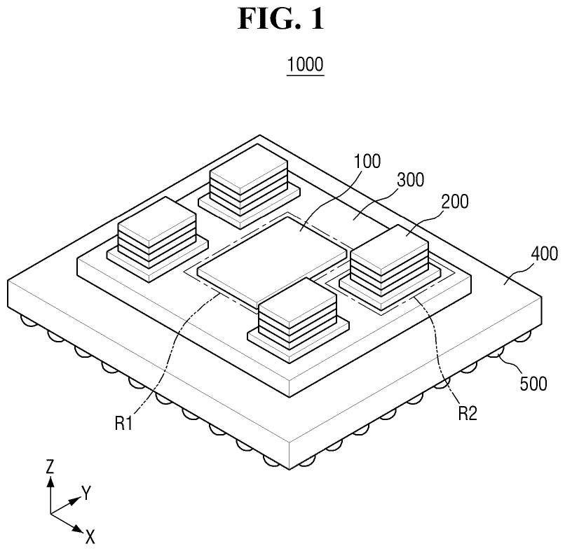

FIG. 1 is an exemplary view illustrating a semiconductor package according to some implementations.

Referring to FIG. 1, a semiconductor package 1000 includes a semiconductor chip 100 and a memory device 200. The semiconductor chip 100 and the memory device 200 may be disposed on the interposer 300, and the interposer 300 may be disposed on a package substrate 400. In detail, the semiconductor chip 100 may be disposed in a region R1 on the interposer 300, and the memory device 200 may be disposed in a region R2 that does not overlap the region R1 on the interposer 300.

FIG. 1 shows that the semiconductor chip 100 is disposed in the region R1 corresponding to a central portion on the interposer 300 and four memory devices 200 are disposed on the interposer 300 in the region R2 near the semiconductor chip 100 to surround the semiconductor chip 100, but the implementations are not limited thereto. For example, the arrangement type of the semiconductor chip 100 and the memory device 200 on the interposer 300 may be varied depending on the implementations.

Also, although four memory devices 200 are shown in FIG. 1, the number of memory devices 200 included in the semiconductor package 1000 is not limited thereto, and the number of memory devices 200 disposed near the semiconductor chip 100 may be varied depending on the implementations.

The semiconductor chip 100 may be, for example, a system-on-chip (SoC). The semiconductor chip 100 may include at least one processor such as a central processing unit (CPU), an application processor (AP), a graphics processing unit (GPU) and a neural processing unit (NPU), and a plurality of memory controllers for controlling the plurality of memory devices 200. The semiconductor chip 100 may transmit and receive signals to and from a corresponding memory device through the memory controller.

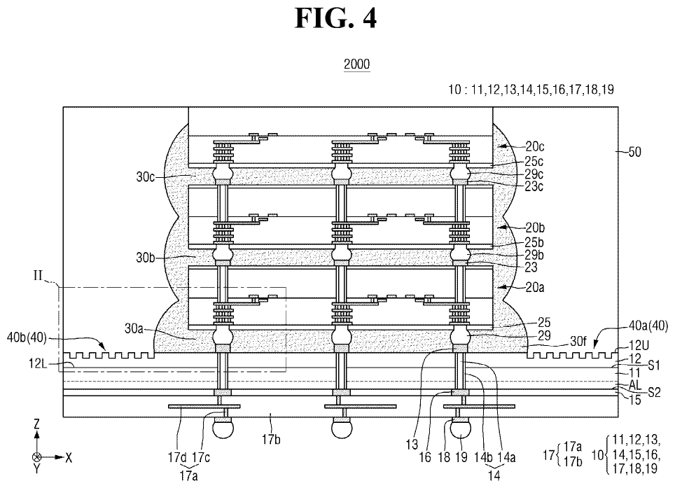

The memory device 200 is a stacked memory device, and may be, for example, a high bandwidth memory (HBM). That is, each of the memory devices 200 disposed on the interposer 300 may be implemented based on the HBM standard, but the implementations are not limited thereto. Each of the memory devices 200 may be implemented based on the GDDR, HMC or Wide I/O standard. A detailed configuration of the memory device 200 will be described later with reference to FIG. 4.

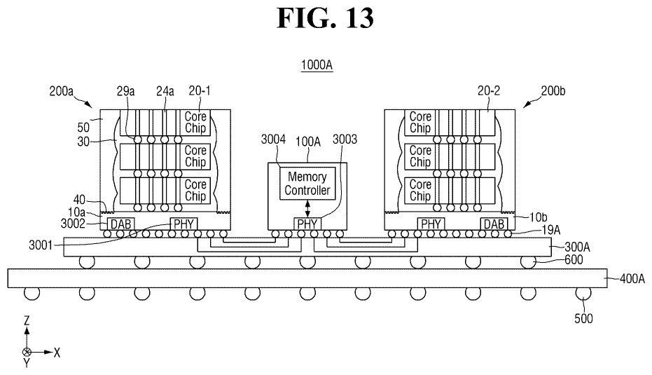

The semiconductor package 1000 may transmit and receive signals to and from another external package or semiconductor devices through solder balls 500 attached to a lower portion of the package substrate 400. A detailed structure of the semiconductor package 1000 will be described later with reference to FIG. 13.

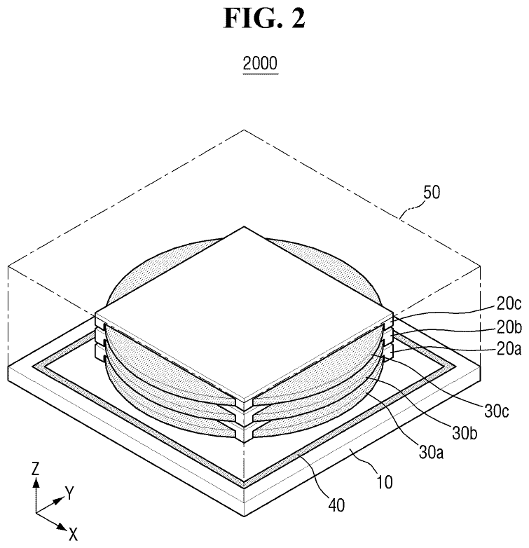

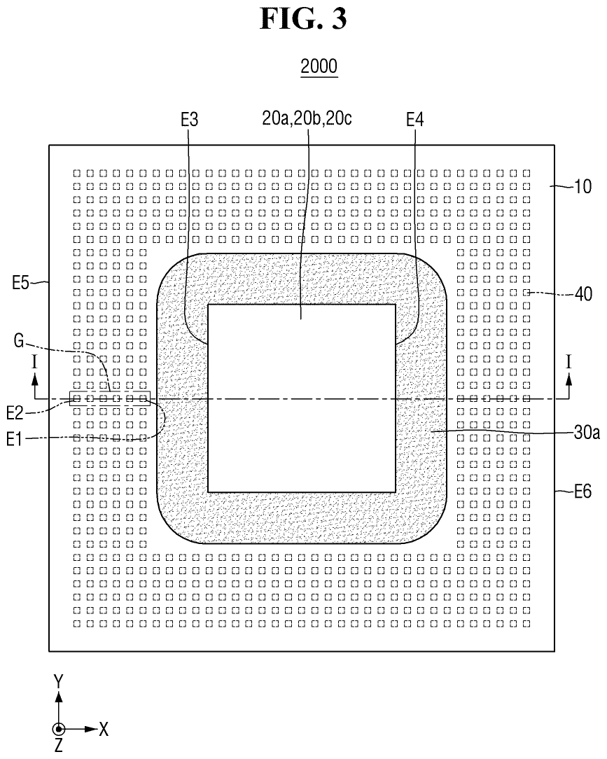

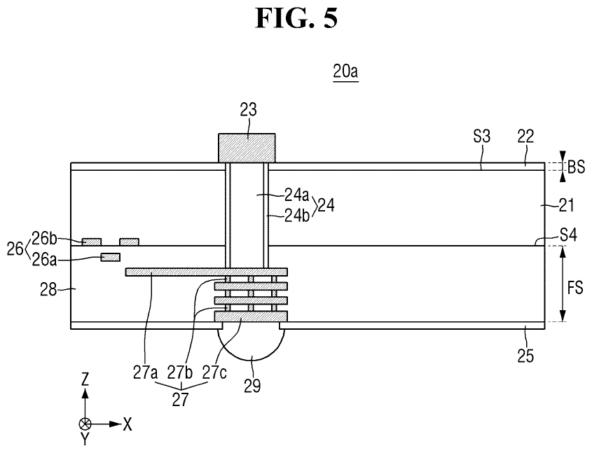

FIG. 2 is an exemplary view illustrating a semiconductor package according to some other implementations. FIG. 3 is an exemplary top view of FIG. 2. FIG. 4 is an exemplary cross-sectional view taken along line I-I of FIG. 3. FIG. 5 is an exemplary cross-sectional view of any one of core chips shown in FIG. 4. Hereinafter, a semiconductor package according to some implementations will be described with reference to FIGS. 2 to 5.

Referring first to FIG. 2, a semiconductor package 2000 may be the memory device 200 described with reference to FIG. 1. The semiconductor package 2000 includes a buffer die 10, core chips 20a, 20b and 20c, adhesive layers 30a, 30b and 30c, and a mold layer 50. FIG. 2 shows that three core chips 20a, 20b and 20c are stacked on the buffer die 10, but the implementations are not limited thereto. The number of core chips stacked on the buffer die 10 may be varied depending on the implementations. For example, in some implementations, the number of core chips stacked on the buffer die 10 may be eight.

The buffer die 10 may be disposed on a plane defined by a first direction X and a second direction Y. In addition, the plurality of core chips 20a, 20b and 20c may be stacked in a third direction Z from a plane on which the buffer die 10 is disposed.

Hereinafter, the third direction Z is defined as an upward direction, and a direction opposite to the third direction Z is defined as a downward direction. For example, ‘an upper surface’ or ‘an upper portion’ may be based on the third direction Z, and a ‘lower surface’ or ‘a lower portion’ may be based on the direction opposite to the third direction Z. In addition, among the plurality of core chips 20a, 20b and 20c stacked on the buffer die 10, the core chip 20a may be disposed on the lowermost end. In addition, the core chip 20c may be disposed on the uppermost end of the plurality of core chips 20a, 20b and 20c.

The plurality of core chips 20a, 20b and 20c may be surrounded by the corresponding adhesive layers 30a, 30b and 30c, respectively. For example, the core chip 20a may be surrounded by the adhesive layer 30a, the core chip 20b may be surrounded by the adhesive layer 30b, and the core chip 20c may be surrounded by the adhesive layer 30c.

The adhesive layers 30a, 30b and 30c may be a non-conductive material layer of an epoxy-based material. For example, the adhesive layers 30a, 30b and 30c may be non-conductive films (NCF), but are not limited thereto. The adhesive layers 30a, 30b and 30c will be described later in detail with reference to FIG. 4.

A plurality of recesses 40 surrounding the core chip 20a, which is disposed on the lowermost end, among the plurality of core chips 20a, 20b and 20c, may be formed on the buffer die 10. In addition, the mold layer 50 may be formed to surround an upper surface of the buffer die 10 and the plurality of core chips 20a, 20b and 20c. The plurality of recesses 40 and the mold layer 50 will be described in detail with reference to FIGS. 3 and 4.

Referring to FIGS. 3 and 4, the buffer die 10 includes a semiconductor substrate 11, a passivation layer 12, a backside pad 13, a through electrode structure 14 (through silicon via (TSV)), a passivation layer 15, a chip pad 16, a redistribution structure 17, a bump pad 18, and a connection member 19.

The semiconductor substrate 11 has a first surface S1 and a second surface S2, which face each other in the third direction Z. For example, the first surface S1 may be an upper surface of the semiconductor substrate 11, and the second surface S2 may be a lower surface of the semiconductor substrate 11. The first surface S1 may be a backside of the semiconductor substrate 11, and the second surface S2 may be a frontside of the semiconductor substrate 11. In some implementations, the semiconductor substrate 11 has an active layer AL at a portion adjacent to the second surface S2. The active layer AL may include a plurality of individual devices of various types. For example, the plurality of individual devices may include various microelectronic devices, such as a complementary metal-oxide semiconductor (CMOS) transistor, a metal-oxide-semiconductor field effect transistor (MOSFET), a large scale integration (LSI), an image sensor such as a CMOS imaging sensor (CIS), a micro-electromechanical system (MEMS), an active device and a passive device.

In some implementations, a material of the semiconductor substrate 11 may include silicon (Si). In addition, the semiconductor substrate 11 may include a semiconductor element such as germanium (Ge), or a compound such as silicon carbide (SiC), gallium arsenide (GaAs), indium arsenide (InAs) and indium phosphide (InP). However, the material of the semiconductor substrate 11 is not limited to that described above.

The passivation layer 12 may be formed on the first surface S1 of the semiconductor substrate 11. The passivation layer 12 may be an upper passivation layer for protecting an upper portion of the buffer die 10. The passivation layer 12 may surround a portion of sides of the through electrode structure 14, and may surround the first surface S1 of the semiconductor substrate 11. In some implementations, the passivation layer 12 may include an insulating material such as an insulating polymer. Alternatively, the passivation layer 12 may be formed of a multi-layer that includes different materials (for example, silicon oxide (SiO₂) and silicon nitride (SiN)). The passivation layer 12 may protect the first surface S1 of the semiconductor substrate 11 and the sides of the through electrode structure 14.

A surface of two surfaces of the passivation layer 12, which is in contact with the first surface S1 of the semiconductor substrate 11, may be a lower surface of the passivation layer 12, and its opposite surface may be an upper surface 12U of the passivation layer 12, wherein the two surfaces of the passivation layer 12 face each other in the third direction Z. The plurality of recesses 40 may be formed on the upper surface 12U of the passivation layer 12. The plurality of recesses 40 may be recessed inward (for example, opposite direction of the third direction Z) from the upper surface 12U of the passivation layer 12.

The plurality of recesses 40 may be disposed to surround the core chip 20a positioned on the lowermost end among the plurality of core chips 20a, 20b and 20c. The number of the plurality of recesses 40 shown in FIGS. 3 and 4 is exemplary, and the number of the plurality of recesses 40 formed in the passivation layer 12 of the buffer die 10 is not limited to that shown in FIGS. 3 and 4.

For example, referring to FIG. 4, seven recesses 40a are formed in the passivation layer 12 of the buffer die 10 in the first direction X with the plurality of core chips 20a, 20b and 20c interposed therebetween, and seven recesses 40b are symmetrically formed in an opposite direction of the first direction X, but the implementations are not limited thereto. The number of the recesses 40a and 40b may be greater or smaller than seven depending on the implementations, and the plurality of recesses may be asymmetrically formed on the upper surface 12U of the passivation layer 12.

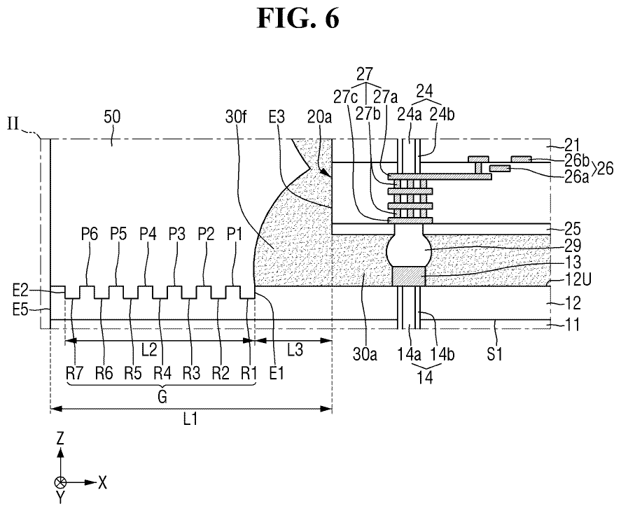

The plurality of recesses 40 may be formed in the passivation layer 12 so as not to overlap the core chip 20a horizontally. That is, the plurality of recesses 40 may be formed in an edge region of the passivation layer 12 to surround the plurality of core chips 20a, 20b and 20c, not a central region in which the plurality of core chips 20a, 20b and 20c are stacked, on the upper surface 12U of the passivation layer 12 of the buffer die 10. The shape of the plurality of recesses 40 will be described later with reference to FIGS. 6 to 10.

The backside pad 13 may be formed on the passivation layer 12. The backside pad 13 may be electrically connected to a through electrode 14a of the through electrode structure 14, and may be electrically connected to bumps 29 of the core chip 20a. The backside pad 13 may include a metal, such as nickel (Ni), copper (Cu), gold (Au), silver (Ag), aluminum (Al), tungsten (W) and titanium (Ti), or an alloy thereof.

The through electrode structure 14 may be formed inside the buffer die 10 to penetrate at least a portion of the buffer die 10 in a vertical direction (e.g., the third direction Z). The through electrode structure 14 includes a through electrode 14a and an insulating spacer 14b covering at least a portion of the sides of the through electrode 14a. The through electrode structure 14 may electrically connect the chip pad 16 with the backside pad 13.

The passivation layer 15 may be formed on the second surface S2 of the semiconductor substrate 11. The passivation layer 15 may be a lower passivation layer for protecting a lower portion of the buffer die 10. The passivation layer 15 may surround sides of the chip pad 16, and may surround the second surface S2 of the semiconductor substrate 11. The passivation layer 15 may expose one surface of the chip pad 16. For example, the passivation layer 15 may expose an upper surface of the chip pad 16 and/or a lower surface of the chip pad 16 to connect the chip pad 16 with the through electrode structure 14 and/or a redistribution pattern 17a. The passivation layer 15 may protect the second surface S2 of the semiconductor substrate 11 and the sides of the chip pad 16. The description of the material included in the passivation layer 15 is the same as the description of the material included in the passivation layer 12 and thus will be omitted.

The chip pad 16 may be disposed on the second surface S2 of the semiconductor substrate 11. The chip pad 16 may include at least one of a metal, such as nickel (Ni), copper (Cu), gold (Au), silver (Ag), aluminum (Al), tungsten (W), titanium (Ti), tantalum (Ta), indium (In), molybdenum (Mo), manganese (Mn), cobalt (Co), tin (Sn), magnesium (Mg), rhenium (Re), beryllium (Be), gallium (Ga) and ruthenium (Ru), or an alloy thereof, but is not limited thereto. The chip pad 16 may be a pad electrically connected to the plurality of individual devices in the active layer AL of the semiconductor substrate 11.

The redistribution structure 17 may be disposed on the second surface S2 of the semiconductor substrate 11. The redistribution structure 17 includes a redistribution pattern 17a electrically connected to the chip pad 16 and a redistribution insulating layer 17b surrounding the redistribution pattern 17a. In some implementations, the redistribution insulating layer 17b may include an insulating material of a photo imagable dielectric (PID) material capable of enabling a photolithography process. For example, the redistribution insulating layer 17b may be formed of photosensitive polyimide (PSPI), but is not limited thereto. The redistribution insulating layer 17b may include oxide or nitride. For example, the redistribution insulating layer 17b may include silicon oxide (SiO₂) or silicon nitride (SiN).

In some implementations, the redistribution pattern 17a may be a conductive pattern electrically connected to the chip pad 16. For example, the redistribution pattern 17a includes a redistribution via pattern 17c extending in the vertical direction (e.g., the third direction Z) in the redistribution insulating layer 17b and a redistribution line pattern 17d extending in a horizontal direction (e.g., the first direction X) in the redistribution insulating layer 17b. In some implementations, the material of the redistribution pattern 17a may be a metal, such as nickel (Ni), copper (Cu), gold (Au), silver (Ag), aluminum (Al), tungsten (W), titanium (Ti), tantalum (Ta), indium (In), molybdenum (Mo), manganese (Mn), cobalt (Co), tin (Sn), magnesium (Mg), rhenium (Re), beryllium (Be), gallium (Ga) and ruthenium (Ru), or an alloy thereof.

The bump pad 18 may be disposed on the redistribution structure 17, and may be a pad electrically connected to the redistribution pattern 17a. In addition, the bump pad 18 may be a pad for connecting the buffer die 10 to a separate semiconductor chip or an external device. In some implementations, a plurality of bump pads 18 may be provided. In addition, the plurality of bump pads 18 may have substantially the same dimension. For example, the plurality of bump pads 18 may substantially have the same height and width. In some implementations, the material of the bump pad 18 may be a metal, such as nickel (Ni), copper (Cu), gold (Au), silver (Ag), aluminum (Al), tungsten (W), titanium (Ti), tantalum (Ta), indium (In), molybdenum (Mo), manganese (Mn), cobalt (Co), tin (Sn), magnesium (Mg), rhenium (Re), beryllium (Be), gallium (Ga) and ruthenium (Ru), or an alloy thereof.

The connection member 19 may be a conductive material attached onto the bump pad 18. For example, the connection member 19 may be a solder ball of a conductive material for connecting the buffer die 10 with a separate semiconductor chip or an external device. In some implementations, the material of the connection member 19 may be a metal, such as nickel (Ni), copper (Cu), gold (Au), silver (Ag), aluminum (Al), tungsten (W), titanium (Ti), tantalum (Ta), indium (In), molybdenum (Mo), manganese (Mn), cobalt (Co), tin (Sn), magnesium (Mg), rhenium (Re), beryllium (Be), gallium (Ga) and ruthenium (Ru), or an alloy thereof, but is not limited thereto.

Then, the plurality of core chips 20a, 20b and 20c stacked on the buffer die 10 will be described with reference to FIGS. 4 and 5. Although only three core chips 20a, 20b and 20c are shown in FIG. 4, the number of core chips included in the semiconductor package 2000 may be varied depending on the implementations.

Also, in FIG. 4, one core chip 20a, one core chip 20b and one core chip 20c are vertically stacked on the buffer die 10, but the number of the core chips 20a, 20b and 20c is not limited thereto. For example, a plurality of core chips 20a may be stacked on the buffer die 10, and a plurality of core chips 20b may be stacked on the plurality of core chips 20a. Likewise, a plurality of core chips 20c may be stacked on the plurality of core chips 20b.

Since the plurality of core chips 20a, 20b and 20c have structures similar to one another, only the core chip 20a will be described with reference to FIG. 5. The description of the core chips 20b and 20c will be replaced with the description of the core chip 20a and only a portion having a difference between the core chip 20c disposed on the uppermost end and the core chip 20a will be described.

Referring to FIGS. 4 and 5, the core chip 20a includes a semiconductor substrate 21, an internal circuit 26, an internal connection pattern 27, a front insulating structure 28, a passivation layer 22, a passivation layer 25, a through electrode structure 24, a backside pad 23, and bumps 29.

The semiconductor substrate 21 includes a third surface S3 and a fourth surface S4, which face each other in the third direction Z. For example, the third surface S3 may be an upper surface of the semiconductor substrate 21, and the fourth surface S4 may be a lower surface of the semiconductor substrate 21. In addition, the third surface S3 may be a backside of the semiconductor substrate 21, and the fourth surface S4 may be a frontside of the semiconductor substrate 21. The core chip 20a includes a frontside structure FS disposed below the fourth surface S4 of the semiconductor substrate 21, and a backside structure BS disposed on the third surface S3 of the semiconductor substrate 21.

The frontside structure FS includes an internal circuit 26, an internal connection pattern 27, a front insulating structure 28 and a passivation layer 25 below the fourth surface S4 of the semiconductor substrate 21.

The internal circuit 26 may include a semiconductor integrated circuit such as a transistor that includes a gate 26a and a source/drain 26b. The internal connection pattern 27 includes a first connection layer 27a, intermediate connection layers 27b below the first connection layer 27a and a second connection layer 27c below the intermediate connection layers 27b. The intermediate connection layers 27b may include a plurality of layers positioned at different height levels between the first connection layer 27a and the second connection layer 27c. The internal connection pattern 27 may include a conductive material.

The internal connection pattern 27 may include a conductive material. At least a portion of the internal circuit 26 and at least a portion of the internal connection pattern 27 may be disposed inside the front insulating structure 28. At least a portion of the internal circuit 26 and at least a portion of the internal connection pattern 27 may be embedded in the front insulating structure 28.

The passivation layer 25 may be formed below the front insulating structure 28. The passivation layer 25 may be a lower passivation layer for protecting a lower portion of the core chip 20a. The passivation layer 25 may include an insulating material such as an insulating polymer. Alternatively, the passivation layer 25 may be formed of a multi-layer that includes different materials (for example, silicon oxide (SiO₂) and the silicon nitride (SiN)).

The backside structure BS includes the passivation layer 22 on the third surface S3 of the semiconductor substrate 21. The passivation layer 22 may be an upper passivation layer for protecting an upper portion of the core chip 20a. The description of the material included in the passivation layer 22 is the same as the description of the material included in the passivation layer 25 and thus will be omitted.

The through electrode structure 24 may be formed in the core chip 20a to penetrate at least a portion of the core chip 20a in the vertical direction (for example, the third direction Z). The through electrode structure 24 includes a through electrode 24a and an insulating spacer 24b covering at least a portion of sides of the through electrode 24a. The through electrode structure 24 may electrically connect the internal connection pattern 27 with the backside pad 23.

The backside pad 23 may be formed on the passivation layer 22. The backside pad 23 may be electrically connected to the through electrode 24a of the through electrode structure 24, and may be electrically connected to bumps 29b of the core chip 20b disposed on the core chip 20a. The backside pad 23 may include a metal, such as nickel (Ni), copper (Cu), gold (Au), silver (Ag), aluminum (Al), tungsten (W) and titanium (Ti), or an alloy thereof.

The bump 29 may be electrically connected to the internal connection pattern 27 by penetrating the passivation layer 25, and may extend below the passivation layer 25. When the core chip 20a is stacked on the buffer die 10 in a thermal compression bonding manner, the bump 29 may be electrically connected to the backside pad 13 of the buffer die 10 in contact with the backside pad 13 of the buffer die 10. The bump 29 may include a solder material.

In this way, the plurality of core chips 20a, 20b and 20c vertically stacked on the buffer die 10 may be semiconductor chips of the same shape and the same type, but the implementations are not limited thereto. For example, the plurality of core chips 20a, 20b and 20c may include different types of semiconductor chips or semiconductor chips of different shapes. For example, referring to FIGS. 3 and 4, lengths of the plurality of core chips 20a, 20b and 20c in the first direction X are all the same as one another, but sizes of the plurality of core chips 20a, 20b and 20c may be varied depending on the implementations.

Referring back to FIG. 4, the through electrode structure may not be formed in the core chip 20c disposed on the uppermost end among the plurality of core chips 20a, 20b and 20c, and the backside pad may not be formed therein.

Meanwhile, the semiconductor package 2000 may be a wafer level package formed by a chip on wafer (CoW) process. For example, the core chip 20a may be formed by forming a plurality of semiconductor chips on a wafer, forming an adhesive layer on a frontside of the plurality of semiconductor chips and dicing the wafer into individual chips. The core chip 20b and the core chip 20c may be also formed in the manner described above. In addition, the semiconductor package 2000 may be formed by stacking the diced individual chips on the buffer die 10 by a thermal compression bonding method and then repeatedly stacking another chip on the stacked chips by the thermal compression bonding method.

In this way, the core chip 20a may be adhered to the buffer die 10 by an adhesive layer 30a formed below the passivation layer 25 of the core chip 20a to constitute the semiconductor package 2000. Likewise, the core chip 20b may be adhered to the core chip 20a by an adhesive layer 30b formed below the passivation layer 25b of the core chip 20b, and the core chip 20c may be adhered to the core chip 20b by an adhesive layer 30c formed below the passivation layer 25c of the core chip 20c.

The adhesive layer 30a may fill a space between the buffer die 10 and the core chip 20a, and may surround sides of the bump 29 and the backside pad 13. The adhesive layer 30b may fill a space between the core chip 20a and the core chip 20b, and may surround sides of a bump 29b and a backside pad 23b. The adhesive layer 30c may fill a space between the core chip 20b and the core chip 20c, and may surround sides of a bump 29c and a backside pad 23c.

According to the implementations, as the plurality of core chips 20a, 20b and 20c are stacked by the thermal compression bonding method, the adhesive layers 30a, 30b and 30c may cover the sides of the plurality of core chips 20a, 20b and 20c and may be connected to one another on the sides of the plurality of core chips 20a, 20b and 20c.

Meanwhile, when the core chip 20a is stacked on the buffer die 10 by the thermal compression bonding method, the adhesive layer 30a formed below the passivation layer 25 of the core chip 20a may overflow to be excessively protruded to the outside of the core chip 20a, thereby forming a filet 30f. At this time, the plurality of recesses 40 may prevent the adhesive layer 30a from being excessively protruded to the outside of the core chip 20a by overflow. The role of the plurality of recesses 40 will be described later with reference to FIG. 6.

The semiconductor package 2000 includes a mold layer 50 surrounding the upper surface of the buffer die 10 and the plurality of core chips 20a, 20b and 20c. The upper surface of the buffer die 10 may be substantially the same as the upper surface 12U of the passivation layer 12. The mold layer 50 may include an epoxy molding compound (EMC), but is not limited thereto, and may include various materials, for example, an epoxy-based material, a thermosetting material, a thermoplastic material, a UV-treated material and the like.

In some implementations, after a core chip to which an adhesive layer is attached is repeatedly attached onto the buffer die 10, the mold layer 50 may be formed, and the mold layer 50 and the buffer die 10 may be cut to form the semiconductor package 2000.

In some implementations, an upper surface of the core chip 20c may be exposed by the mold layer 50. That is, the upper surface of the core chip 20c and an upper surface of the mold layer 50 may be placed on the same plane.

FIGS. 6 to 10 are enlarged views of the region II of FIG. 4. Hereinafter, a plurality of recesses will be described with reference to FIGS. 6 to 10.

Referring to FIGS. 3 and 6 together, the plurality of recesses 40 includes a recess group G. The recess group G may extend lengthwise in the first direction X. The recess group G is an example of any recesses extending in the first direction X of the plurality of recesses 40, and the description of the recess group G may be equally applied to any recesses extending in the first direction X or any recesses extending in the second direction Y.

The recess group G includes a plurality of recesses R1 to R7 disposed to be aligned in the first direction X. A plurality of protrusions P1 to P6 may be formed between the plurality of recesses 40, respectively. In this way, the recesses R1 to R7 of a shape concavely recessed inward from the upper surface 12U of the passivation layer 12 and the protrusions P1 to P6 convexly protruded between the recesses from the plane in which the recesses are formed may be periodically and repeatedly formed on the upper surface 12U of the passivation layer 12. At this time, upper surfaces of the protrusions P1 to P6 may be positioned on the substantially same plane as the upper surface 12U of the passivation layer 12. In FIG. 6, seven recesses R1 to R7 are formed on the upper surface 12U of the passivation layer 12, but the number of the recesses formed on the upper surface 12U of the passivation layer 12 may be any natural number of 2 or more.

Referring to FIGS. 3, 4 and 6 together, the recess group G includes a first edge E1 and a second edge E2, which face each other in the first direction X. In addition, the core chip 20a includes a third edge E3 and a fourth edge E4, which face each other in the first direction X. In addition, the buffer die 10 includes a fifth edge E5 and a sixth edge E6, which face each other in the first direction X. The third edge E3 of the core chip 20a and the fifth edge E5 of the buffer die 10 may be disposed on the same side with respect to the center of the core chip 20a. In addition, the fourth edge E4 of the core chip 20a and the sixth edge E6 of the buffer die 10 may be disposed on the same side with respect to the center of the core chip 20a. In addition, the first edge E1 of the recess group G may be closer to the third edge E3 of the core chip 20a than the second edge E2, and the second edge E2 of the recess group G may be closer to the fifth edge E5 of the buffer die 10 than the first edge E1.

In some implementations, when a length from the third edge E3 of the core chip 20a to the fifth edge E5 of the buffer die 10 is L1 and a length between the first edge E1 and the second edge E2 of the recess group G is L2, 3/20≤L2/L1≤1 may be obtained. Further, in some implementations, L2 may be 30 μm or more and 250 μm or less. When L2/L1 is smaller than 3/20, the plurality of recesses R1 to R7 may not provide sufficient roughness for preventing the adhesive layer 30a between the buffer die 10 and the core chip 20a from overflowing. Therefore, the recesses may fail to sufficiently reduce the filet formed as the adhesive layer 30a is excessively protruded to the outside of the core chip 20a.

In some implementations, the adhesive layer 30a may be in contact with the first edge E1 of the recess group G. A distance L3 from the first edge E1 of the recess group G to the third edge E3 of the core chip 20a may be 50 μm or more and 200 μm or less.

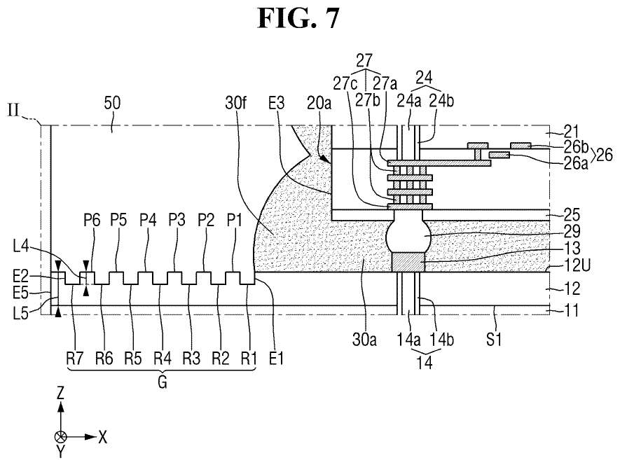

Referring to FIG. 7, lengths L4 of the plurality of recesses R1 to R7, which are included in the recess group G, in the third direction Z may be substantially the same as one another. In some implementations, when the length of the passivation layer 12 in the third direction Z is L5, 3/20≤L4/L5≤½ may be obtained. Also, in some implementations, LA may be 0.5 μm or more and 10 μm or less. When L4/L5 is smaller than 3/20, the plurality of recesses R1 to R7 may not provide sufficient roughness to prevent the adhesive layer 30a between the buffer die 10 and the core chip 20a from overflowing. Therefore, the recesses may fail to sufficiently reduce the filet formed as the adhesive layer 30a is excessively protruded to the outside of the core chip 20a. Also, when L4/L5 is greater than ½, the passivation layer 12 may not sufficiently protect the first surface S1 of the semiconductor substrate 11.

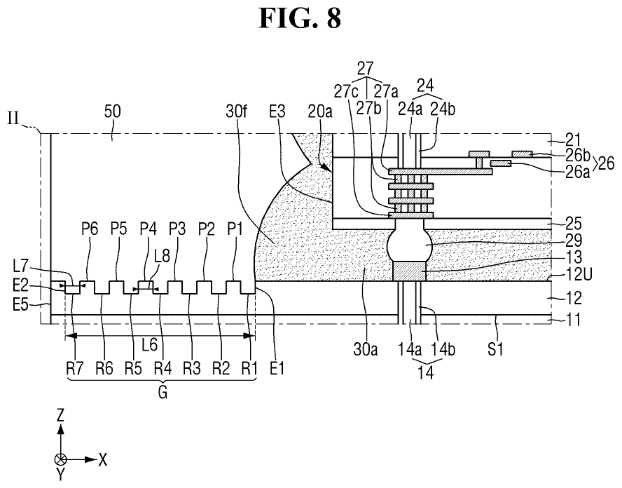

Next, referring to FIG. 8, a length L6 of the recess group G may be defined as a distance between the first edge E1 and the second edge E2. Also, lengths L7 of the plurality of recesses R1 to R7, which are included in the recess group G, in the first direction X may be substantially the same as one another. In accordance with the implementations, lengths L8 of the protrusions P1 to P6 in the first direction X may be substantially the same as one another, and may be the same as the lengths L7 of the recesses R1 to R7 in the first direction X, but are not limited thereto.

In some implementations, ⅕≤L7/L6≤ 33/100 may be obtained. Also, in some implementations, L7 may be 0.5 μm or more and 10 μm or less. When L7/L6 is smaller than ⅕ or L7/L6 is greater than 33/100, the plurality of recesses R1 to R7 may not provide sufficient roughness to prevent the adhesive layer 30a between the buffer die 10 and the core chip 20a from overflowing. Therefore, the recesses may fail to sufficiently reduce the filet formed as the adhesive layer 30a is excessively protruded to the outside of the core chip 20a.

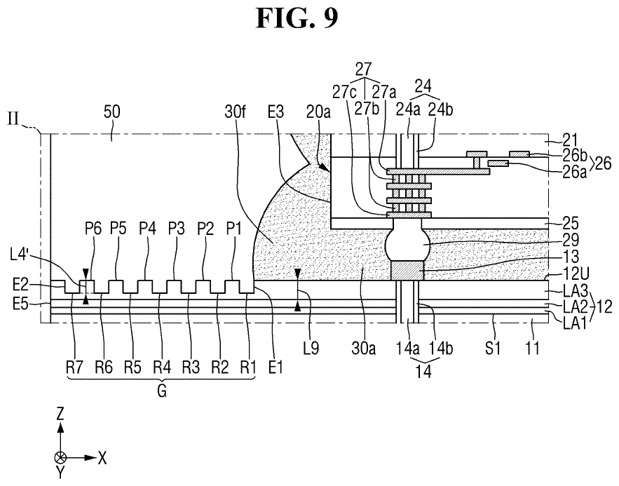

Next, referring to FIG. 9, the passivation layer 12 includes a first layer LA1, a second layer LA2 and a third layer LA3. The first to third layers LA1 to LA3 may be sequentially stacked on the first surface S1 of the semiconductor substrate 11. The first layer LA1 and the third layer LA3 may be silicon oxide layers that include silicon oxide (SiO₂), and the second layer LA2 may be a silicon nitride layer that includes silicon nitride (SiN). The plurality of recesses R1 to R7 may be formed in the third layer LA3 of the passivation layer 12. That is, the upper surface 12U of the passivation layer 12 may be placed on the substantially same plane as the upper surface of the third layer LA3, and the plurality of recesses R1 to R7 may be formed to be recessed inward from the upper surface of the third layer LA3.

In some implementations, lengths L4′ of the plurality of recesses R1 to R7 in the third direction Z may be smaller than a length L9 of the third layer LA3 in the third direction Z. Therefore, the second layer LA2 may not be exposed by the plurality of recesses 40.

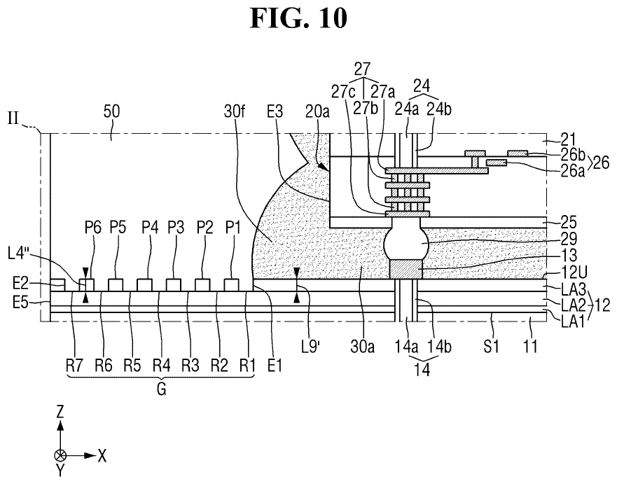

Referring next to FIG. 10, the passivation layer 12 includes a first layer LA1, a second layer LA2 and a third layer LA3. Hereinafter, a description redundant to FIG. 9 will be omitted, and the following description will be based on differences from FIG. 9. In some implementations, lengths L4″ of the plurality of recesses R1 to R7 in the third direction Z may be the same as a length L9′ of the third layer in the third direction Z or may be greater than the length L9′ of the third layer in the third direction Z. Therefore, the plurality of recesses R1 to R7 may be in contact with an upper surface of the second layer LA2, or may be formed by penetrating a portion of the upper surface of the second layer LA2 in the third direction Z. Therefore, at least a portion of the second layer LA2 may be exposed by the plurality of recesses R1 to R7.

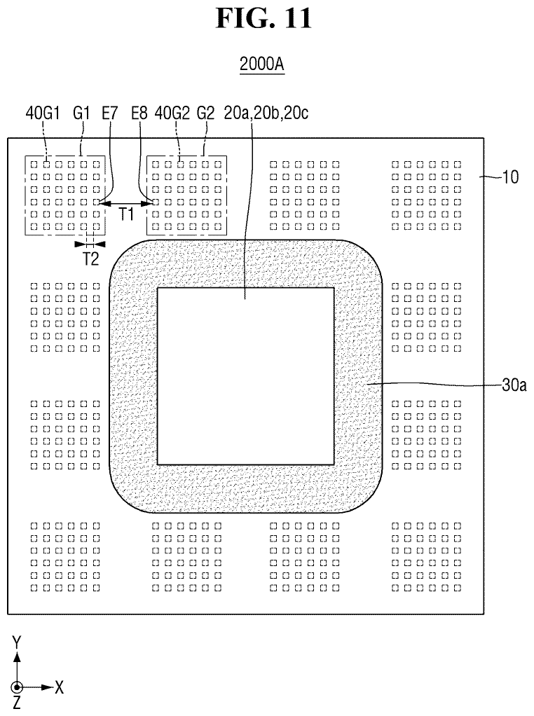

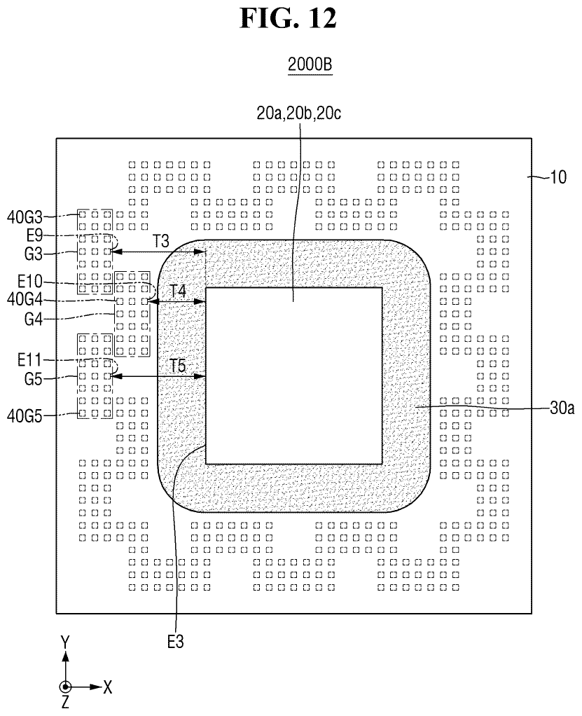

FIG. 11 is an exemplary view illustrating a semiconductor package according to some other implementations. FIG. 12 is an exemplary view illustrating a semiconductor package according to some other implementations. Hereinafter, the following description will be based on differences from the previous implementations.

First, referring to FIG. 11, unlike FIG. 3, the plurality of recesses 40 formed to surround the core chip 20a without overlapping the core chip 20a horizontally includes a recess group G1 and a recess group G2. The recess group G1 includes a plurality of recesses 40G1, and the recess group G2 includes a plurality of recesses 40G2. An edge closest to the recess group G2 among edges of the recess group G1, which face each other in the first direction X, may be an edge E7. Also, an edge closest to the recess group G1 among edges of the recess group G2, which face each other in the first direction X, may be an edge E8. A length of the edge E7 and the edge E8 in the first direction X may be T1. In addition, an interval between the recesses 40G1, which are included in the recess group G1, in the first direction X may be T2.

In some implementations, T1 may be greater than T2. Therefore, a region in which the recesses 40 are not formed between the plurality of recesses 40G1 and the plurality of recesses 40G2 may exist in the upper surface 12U (shown in FIG. 4) of the passivation layer 12 (shown in FIG. 4) of the buffer die 10 as the recess groups G1 and G2 are periodically disposed to surround the core chip 20a. Therefore, the recesses 40 formed to surround the core chip 20a may be formed to surround the core chip 20a in a partially disconnected shape.

Referring to FIG. 12, unlike FIG. 3, the plurality of recesses 40 formed to surround the core chip 20a without overlapping the core chip 20a horizontally includes a recess group G3, a recess group G4, and a recess group G5. The recess group G3 includes a plurality of recesses 40G3, the recess group G4 includes a plurality of recesses 40G4, and the recess group G5 includes a plurality of recesses 40G5. The recess group G3 may be disposed above the recess group G4 in the second direction Y, and the recess group G4 may be disposed above the recess group G5 in the second direction Y.

An edge closest to the edge E3 of the core chip 20a among edges of the recess group G3, which face each other in the first direction X, may be an edge E9. Also, an edge closest to the edge E3 of the core chip 20a among edges of the recess group G4, which face each other in the first direction X, may be an edge E10. Also, an edge closest to the edge E3 of the core chip 20a among edges of the recess group G5, which face each other in the first direction X, may be an edge E11. A length of the edge E3 and the edge E9 in the first direction X may be T3, a length of the edge E3 and the edge E10 in the first direction X may be T4, and a length of the edge E3 and the edge E11 in the first direction X may be T5.

In some implementations, T3 may be the same as T5, and T4 may be smaller than T3 and T5. Also, the recess groups G3, G4 and G5 may be periodically disposed on the upper surface 12U (shown in FIG. 4) of the passivation layer 12 (shown in FIG. 4) of the buffer die 10 to surround the core chip 20a. Therefore, the recesses 40 formed to surround the core chip 20a may be formed to surround the core chip 20a in a zigzag shape.

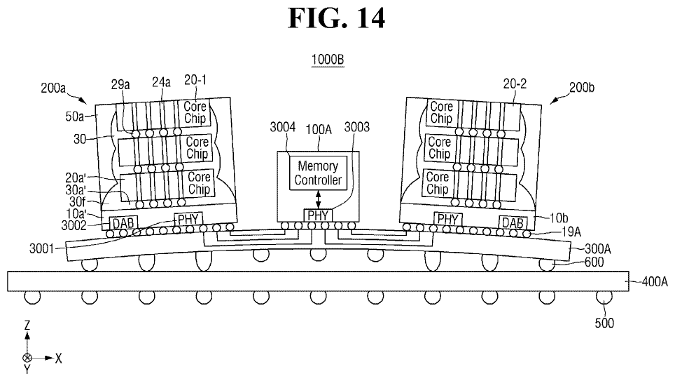

FIGS. 13 and 14 are exemplary views illustrating a semiconductor package according to some implementations.

Referring first to FIG. 13, a semiconductor package 1000A may correspond to the semiconductor package 1000 of FIG. 1. Hereinafter, a description redundant to the previous implementations will be omitted, and the following description will be based on differences from the previous implementations. The semiconductor package 1000A includes a first memory device 200a, a second memory device 200b, a semiconductor chip 100A, an interposer 300A and a package substrate 400A. The first memory device 200a, the second memory device 200b and the semiconductor chip 100A may be disposed in regions on the interposer 300A, which do not overlap each other. In some implementations, the first memory device 200a and the second memory device 200b may be disposed in the first direction X with the semiconductor chip 100A interposed therebetween, but the present disclosure is not limited thereto.

The first memory device 200a includes a buffer die 10a and core chips 20-1. The second memory device 200b includes a buffer die 10b and core chips 20-2. Each of the first memory device 200a and the second memory device 200b may correspond to the semiconductor package 2000 shown in FIG. 4. Since the description of the first memory device 200a and the description of the second memory device 200b are redundant to each other, the description of the second memory device 200b will be replaced with the description of the first memory device 200a.

Each of the core chips 20-1 of the first memory device 200a may include a memory cell array. The buffer die 10a includes a physical layer (PHY) 3001 and a direct access region (DAB) 3002. The physical layer 3001 may be electrically connected to the physical layer 3003 of the semiconductor chip 100A through the interposer 300A. The first memory device 200a may receive signals from the semiconductor chip 100A through the physical layer 3001 or transmit the signals to the semiconductor chip 100A. The physical layer 3001 may include interface circuits of the buffer die 10a.

The direct access region 3002 may provide an access path capable of testing the first memory device 200a without passing through the semiconductor chip 100A. The direct access region 3002 may include conductive means (e.g., port or pin) capable of directly performing communication with an external test device. The test signal and data received through the direct access region 3002 may be transmitted to the core chips 20-1 through the through electrode 24a. The data read from the core chips 20-1 to test the core chips 20-1 may be transmitted to the test device through the through electrode 24a and the direct access region 3002. Therefore, a direct access test for the core chips 20-1 may be performed.

The buffer die 10a and the core chips 20-1 may be electrically connected to each other through the through electrode 24a and bumps 29a. The through electrode 24a and the bumps 29a may correspond to the through electrode 24a and the bump 29 of FIG. 5, respectively. The buffer die 10a may receive signals provided to each channel through bumps 19A allocated for each channel from the semiconductor chip 100A. For example, the bumps 19A may correspond to the bumps 19 of FIG. 4, and may be micro-bumps.

The semiconductor chip 100A may execute applications supported by the semiconductor package 1000A by using the memory devices 200a and 200b. For example, the semiconductor chip 100A may include at least one of a Central Processing Unit (CPU), an Application Processor (AP), a Graphic Processing Unit (GPU), a Neural Processing Unit (NPU), a Tensor Processing Unit (TPU), a Vision Processing Unit (VPU), an Image Chirp Processor (ISP) or a Digital Signal Processor (DSP).

The semiconductor chip 100A includes a physical layer 3003 and a memory controller 3004. The physical layer 3003 may include input/output circuits for transmitting and receiving signals to and from the physical layer 3001 of the first memory device 200a. The semiconductor chip 100A may provide various signals to the physical layer 3001 through the physical layer 3003. The signals provided to the physical layer 3001 may be transferred to the core chips 20-1 through interface circuits of the physical layer 3001 and the through electrode 24a.

The memory controller 3004 may control an overall operation of the first memory device 200a. The memory controller 3004 may transmit signals for controlling the first memory device 200a to the first memory device 200a through the physical layer 3003.

The interposer 300A may connect the first memory device 200a to the semiconductor chip 100A. The interposer 300A may connect the physical layer 3001 of the first memory device 200a to the physical layer 3003 of the semiconductor chip 100A, and may provide physical paths formed using conductive materials. Therefore, the first memory device 200a and the semiconductor chip 100A may be stacked on the interposer 300A to transmit and receive signals to and from each other.

Bumps 600 may be attached to an upper portion of the package substrate 400A, and solder balls 500 may be attached to a lower portion of the package substrate 400A. For example, the bumps 600 may be flip-chip bumps. The interposer 300A may be stacked on the package substrate 400A through the bumps 600. The semiconductor package 1000A may transmit and receive signals to and from another external package or semiconductor devices through the solder balls 500. The solder balls 500 may correspond to the solder balls 500 of FIG. 1. For example, the package substrate 400A may be a printed circuit board (PCB).

Referring to FIG. 14, unlike FIG. 13, a plurality of recesses may not be formed on an upper surface of a buffer die 10a′ of a semiconductor package 1000B. In this case, an adhesive layer 30a′ between the buffer die 10a′ and a core chip 20a′ may overflow and may pile up around the outside of the core chip 20a′ to form a filet 30f. As such, the filet 30f may absorb moisture near sidewalls of a mold layer 50a covering the plurality of core chips 20-1 including the upper surface of the buffer die 10a′ and the core chip 20a′. Therefore, as shown in FIG. 14, warpage of the interposer 300A may be severe to cause a non-wet defect, and a contact defect between the interposer 300A and the package substrate 400A may occur at a lower side of the semiconductor chip 100A.

Therefore, in some implementations, as shown in FIG. 4, the plurality of recesses 40 may be formed on the upper surface 12U of the passivation layer 12 of the buffer die 10 to reduce a filet formed as the adhesive layer 30a between the buffer die 10 and the core chip 20a overflows to pile up around the outside of the core chip 20a. Therefore, a non-wet defect and a contact defect of the semiconductor package may be resolved.

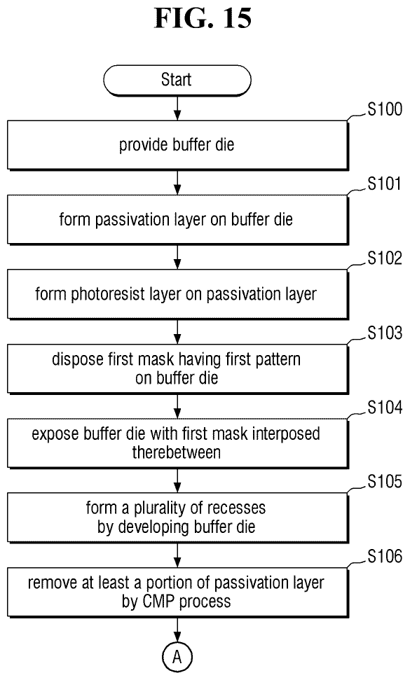

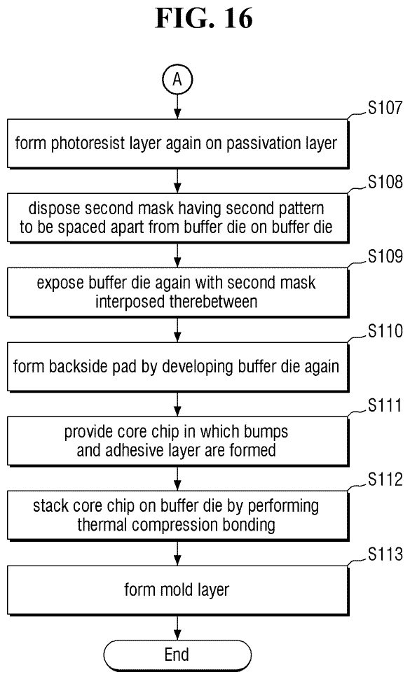

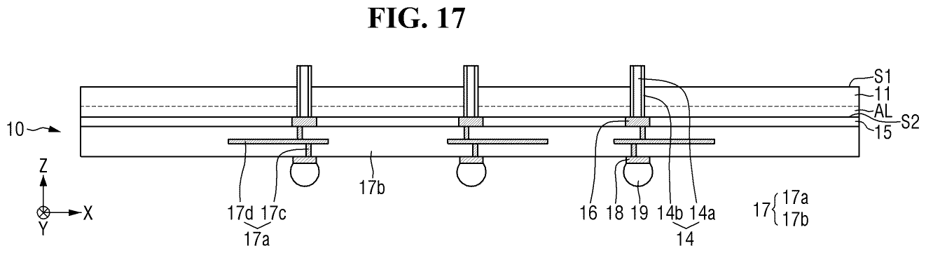

FIGS. 15 and 16 are exemplary flow charts illustrating a fabricating method of a semiconductor package according to some implementations. FIGS. 17 to 29 are exemplary views illustrating intermediate steps to describe a fabricating method of a semiconductor package according to some implementations. Hereinafter, the fabricating method of a semiconductor package according to some implementations will be described with reference to FIGS. 15 to 28.

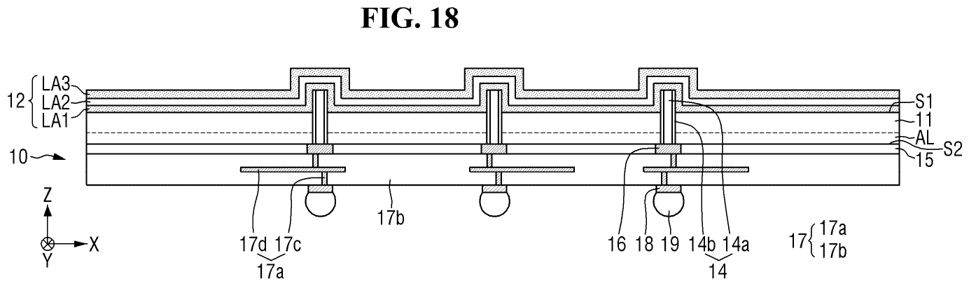

Referring to FIGS. 15 and 17, a buffer die 10 is provided (S100). The buffer die 10 includes a semiconductor substrate 11 that includes a first surface S1 and a second surface S2, which face each other in the third direction Z. In addition, the buffer die 10 includes a through electrode 14a penetrating at least a portion of the buffer die 10 in a vertical direction (for example, the third direction Z). Next, referring to FIGS. 15 and 18, a passivation layer 12 is formed on a first surface S1 of the semiconductor substrate 11 (S101). The passivation layer 12 includes a first layer LA1, a second layer LA2 and a third layer LA3, which are sequentially stacked in the third direction Z on the first surface S1 of the semiconductor substrate 11. In accordance with the implementations, the first layer LA1 and the third layer LA3 may be silicon oxide layers that include silicon oxide (SiO2), and the second layer LA2 may be a silicon nitride layer that includes silicon nitride (SiN). In accordance with the implementations, the buffer die 10 (shown in FIG. 17) may be provided to include the passivation layer 12.

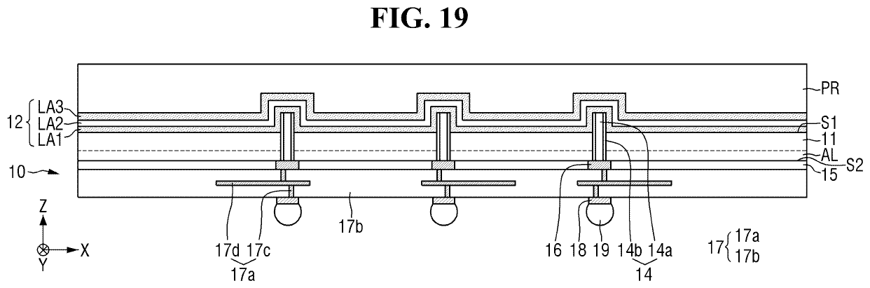

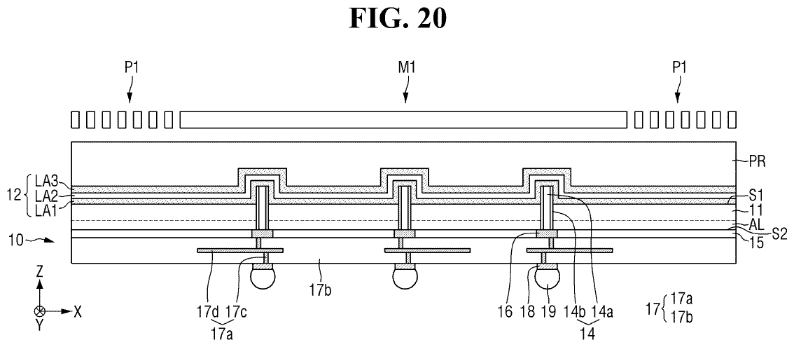

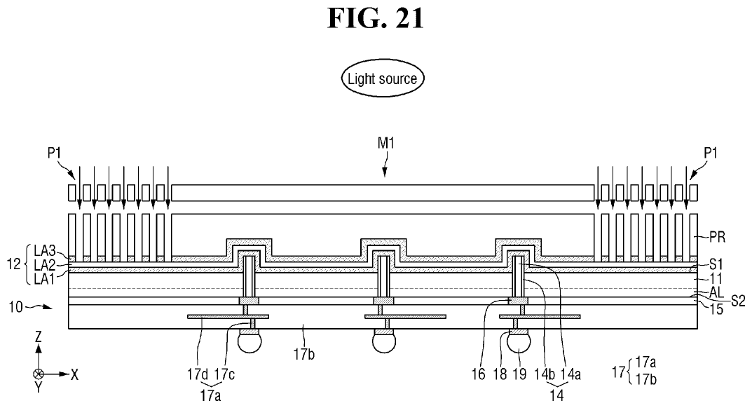

Referring to FIGS. 15 and 19, a photoresist layer PR is formed on the passivation layer 12 (S102). The photoresist layer PR may be a positive photo resist. Referring to FIGS. 15 and 20, the passivation layer 12 is formed on the first surface S1 of the first semiconductor substrate 11, and a first mask M1 having a first pattern P1 is formed on the buffer die 10 in which the photoresist layer PR is formed on the passivation layer 12 (S103). The first mask M1 may be disposed to be spaced apart from the photoresist layer PR as much as a predetermined interval in the third direction Z. Next, referring to FIGS. 15 and 21, the buffer die 10 is exposed with the first mask M1 interposed therebetween (S104). In this case, a light source may be disposed above the first mask M1 in the third direction Z.

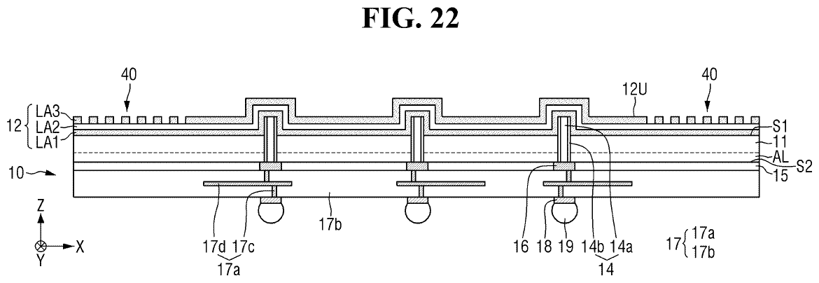

Next, referring to FIGS. 15 and 22, the first mask M1 is removed, and the buffer die 10 is developed to form a plurality of recesses 40 on the upper surface 12U of the passivation layer 12 (S105). Referring to FIGS. 21 and 22 together, an exposed portion in an exposure process of FIG. 21 may be removed in a developing process. Therefore, a portion of the upper surface 12U of the passivation layer 12, which corresponds to the first pattern P1 of the first mask M1, may be removed in the exposure process to form the plurality of recesses 40 recessed inward the passivation layer 12 from the upper surface 12U of the passivation layer 12. In this way, the plurality of recesses 40 may be formed in a portion of the upper surface 12U of the passivation layer 12, which is aligned with the first pattern P1 of the first mask M1 in the vertical direction (e.g., the third direction Z).

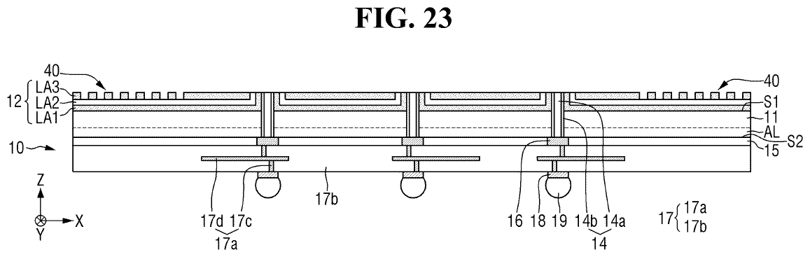

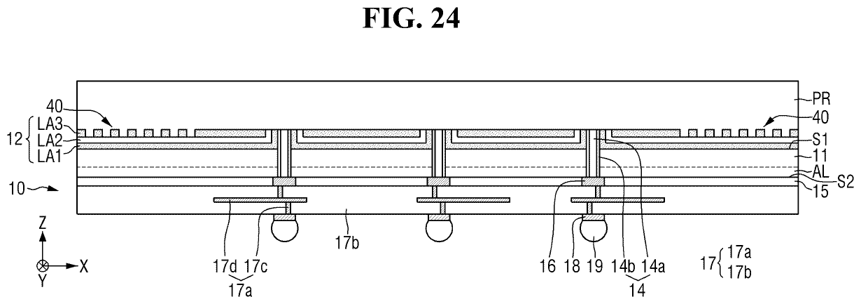

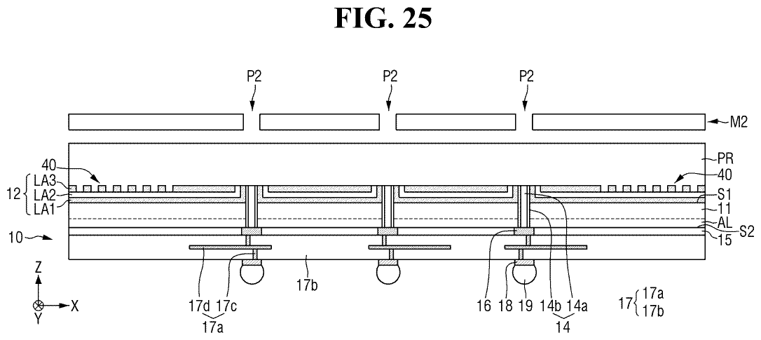

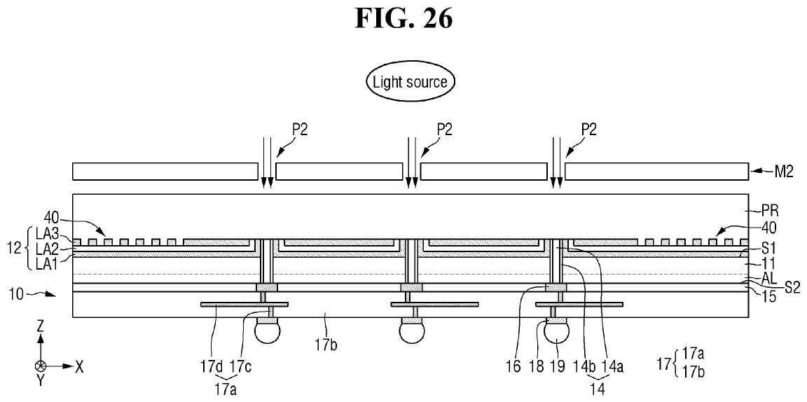

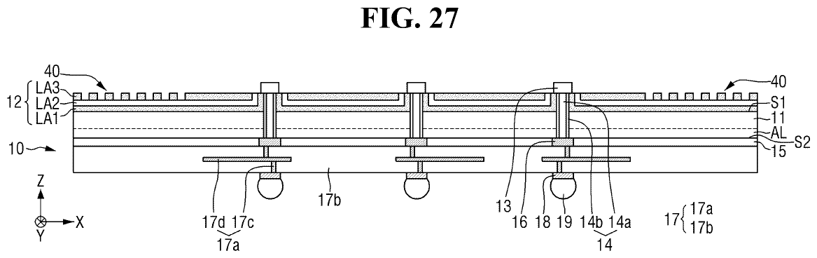

Referring to FIGS. 15 and 23, the upper surface of the buffer die 10 is planarized by a Chemical Mechanical Polishing (CMP) process (S106). At this time, at least a portion of the passivation layer 12 may be removed. Next, referring to FIGS. 16 and 24, a photoresist layer PR is formed on the planarized passivation layer 12 again (S107). Referring to FIGS. 16 and 25, a second mask M2 having a second pattern P2 is disposed on the buffer die 10 in which the photoresist layer PR is formed again (S108). The second mask M2 may be disposed to be spaced apart from the photoresist layer PR as much as a predetermined interval in the third direction Z. Referring to FIGS. 16 and 26, the buffer die 10 is exposed again with the second mask M2 interposed therebetween (S109). In this case, a light source may be disposed above the second mask M2 in the third direction Z. Next, referring to FIGS. 16 and 27, the second mask M2 is removed, and the buffer die 10 is again developed to form a backside pad 13 connected to the through electrode 14a on the passivation layer 12 (S110).

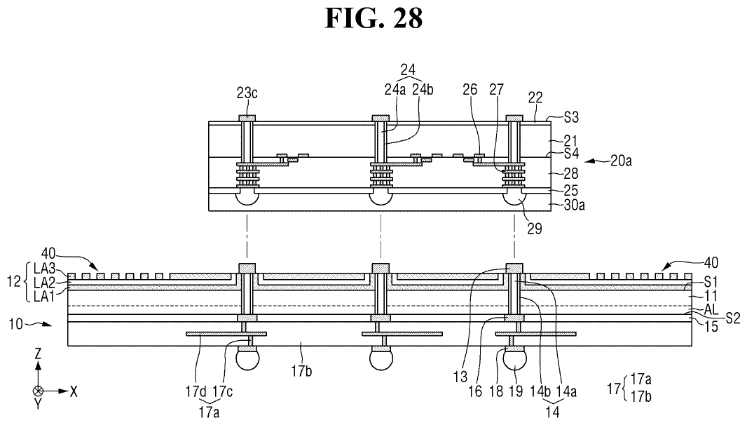

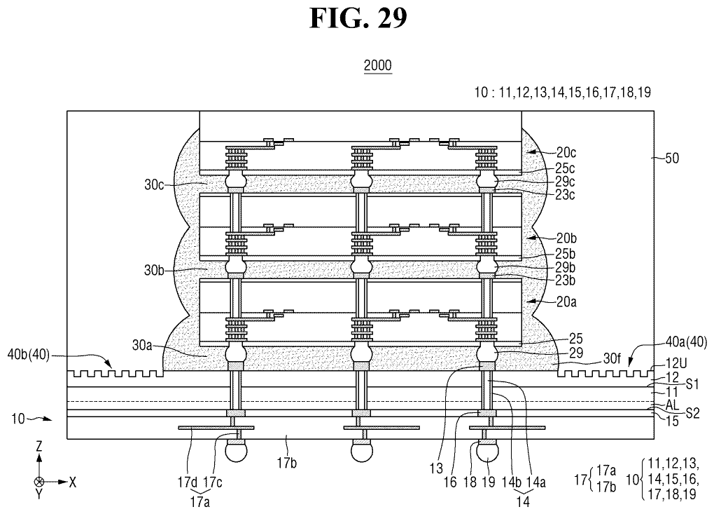

Referring to FIGS. 16 and 28, a core chip 20a in which bumps 29 and an adhesive layer 30a are formed is provided (S111), and the core chip 20a is stacked on the buffer die 10 by performing thermal compression bonding (S112). The core chip 20a may correspond to the core chip 20a of FIG. 4. A lower portion of the core chip 20a may correspond to a fourth surface S4 of the semiconductor substrate 21, and an upper portion of the core chip 20a may correspond to a third surface S3 of the semiconductor substrate 21. In addition, a lower portion of the core chip 20a may be a lower surface of the passivation layer 25. Bumps 29 and an adhesive layer 30a covering a lower portion of the bump 29 and the core chip 20a may be formed below the core chip 20a. At this time, the core chip 20a may be stacked on the buffer die 10 by applying heat and pressure to the upper portion of the core chip 20a so that the backside pad 13 of the buffer die 10 and the bump 29 of the core chip 20a are in contact with each other. In this way, a plurality of core chips including adhesive layers may be vertically stacked on the buffer die 10. Referring to FIGS. 16 and 29, after the plurality of core chips 20a, 20b and 20c are stacked on the buffer die 10, a mold layer 50 surrounding the upper surface of the buffer die 10 and the plurality of core chips 20a, 20b and 20c is formed (S113).

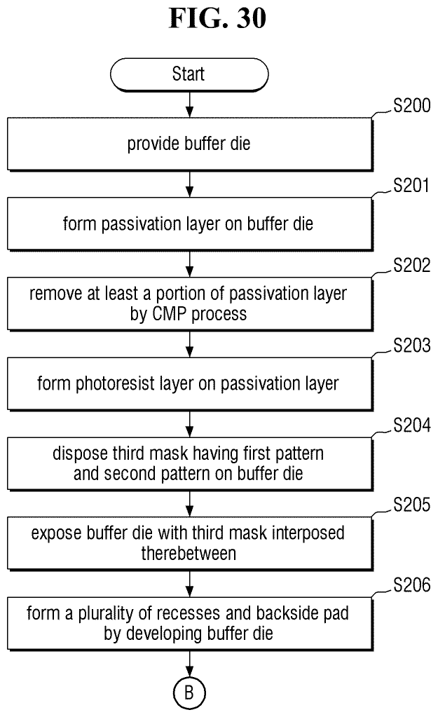

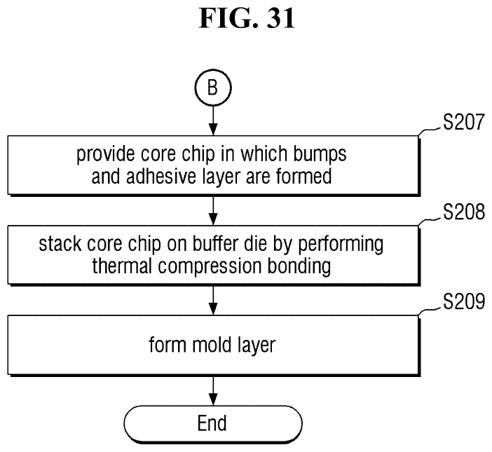

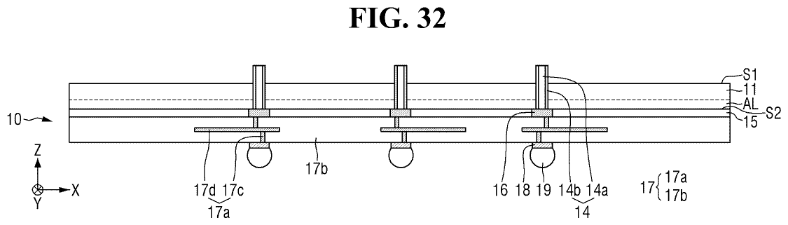

FIGS. 30 and 31 are exemplary flow charts illustrating a fabricating method of a semiconductor package according to some other implementations. FIGS. 32 to 40 are exemplary views illustrating intermediate steps to describe a fabricating method of a semiconductor package according to some other implementations. Hereinafter, the fabricating method of a semiconductor package according to some other implementations will be described with reference to FIGS. 30 to 40. Hereinafter, a description redundant to the previous implementations will be omitted, and the following description will be based on differences from the previous implementations.

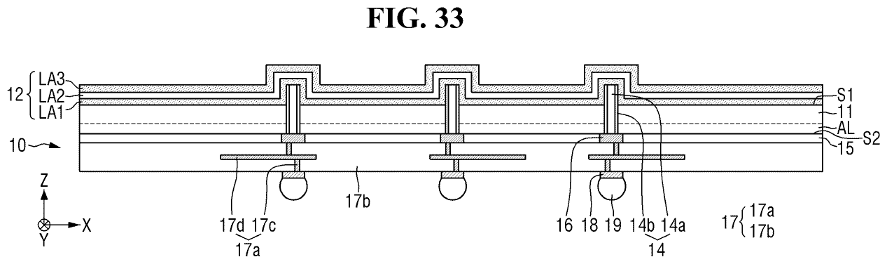

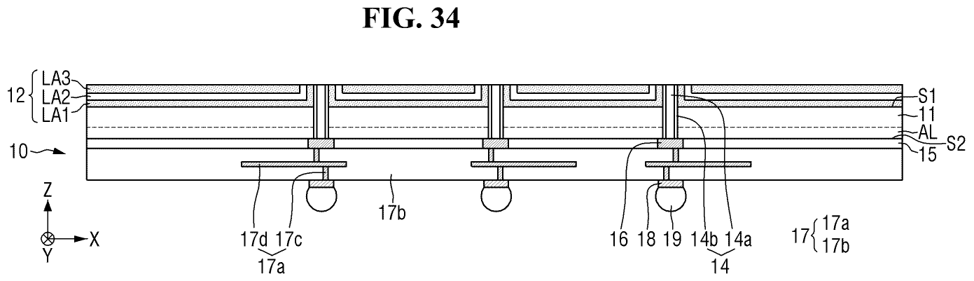

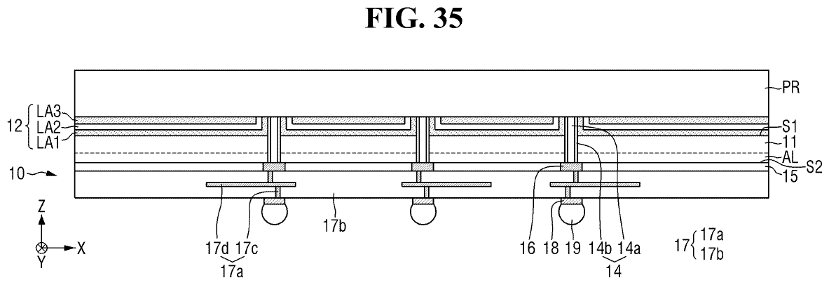

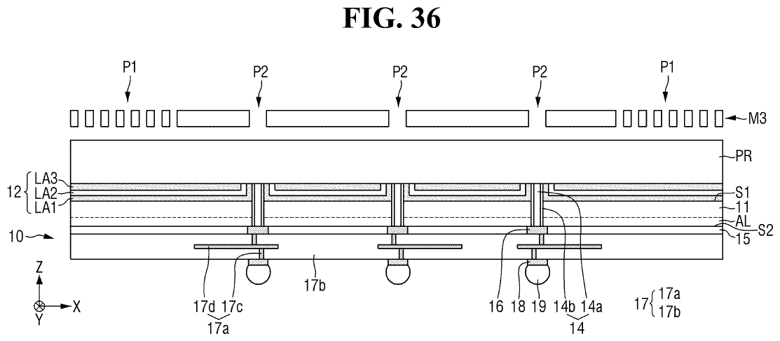

First, referring to FIGS. 30 and 32, a buffer die 10 is provided (S200). Next, referring to FIGS. 30 and 33, a passivation layer 12 is formed on the buffer die 10 (S201). In accordance with the implementations, the passivation layer 12 may be included in the buffer die 10. Next, referring to FIGS. 30 and 34, an upper surface of the buffer die 10 is planarized by a CMP process (S202). At this time, at least a portion of the passivation layer 12 may be removed together. Next, referring to FIGS. 30 and 35, a photoresist layer PR is formed on the planarized passivation layer 12 (S203). Referring to FIGS. 30 and 36, a third mask M3 having a first pattern P1 and a second pattern P2 is disposed on the buffer die 10 (S204). The third mask M3 may be disposed to be spaced apart from the photoresist layer PR as much as a predetermined interval in the third direction Z. In this way, a photolithography process may be performed at a time by using the third mask M3 in which both the first pattern P1 for forming the plurality of recesses 40 in the passivation layer 12 and the second pattern P2 for forming a backside pad 13 (shown in FIG. 4) on the passivation layer 12 are included.

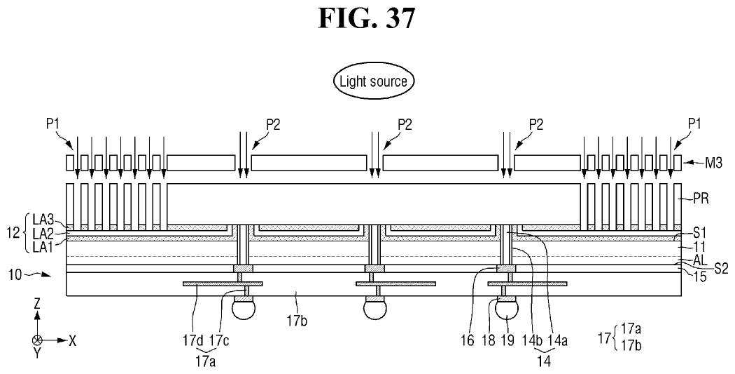

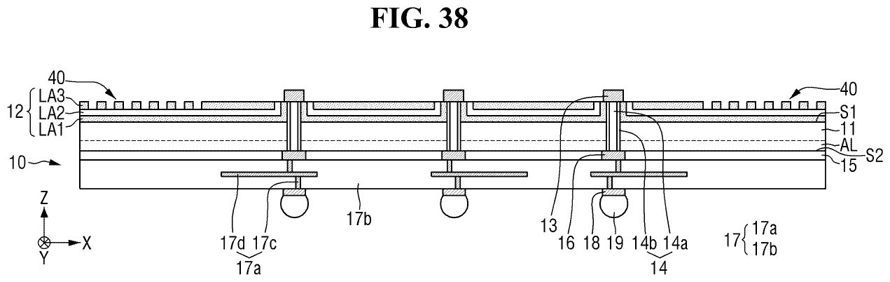

Next, referring to FIGS. 30 and 37, the buffer die 10 is exposed with the third mask M3 interposed therebetween (S205). In this case, a light source may be disposed above the third mask M3 in the third direction Z. Referring to FIGS. 30 and 38, the third mask M3 is removed, and the buffer die 10 is developed to form a plurality of recesses 40 and a backside pad 13 on the upper surface 12U of the passivation layer 12 (S206). The plurality of recesses 40 may be formed in a portion of the upper surface 12U of the passivation layer 12, which is aligned with the first pattern P1 of the third mask M3 in the vertical direction. In addition, the backside pad 13 may be formed in a portion of the upper surface 12U of the passivation layer 12, which is aligned with the second pattern P2 of the third mask M3 in the vertical direction.

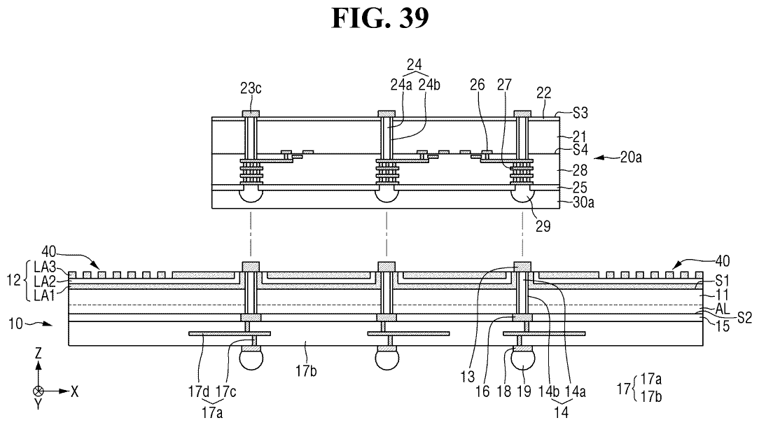

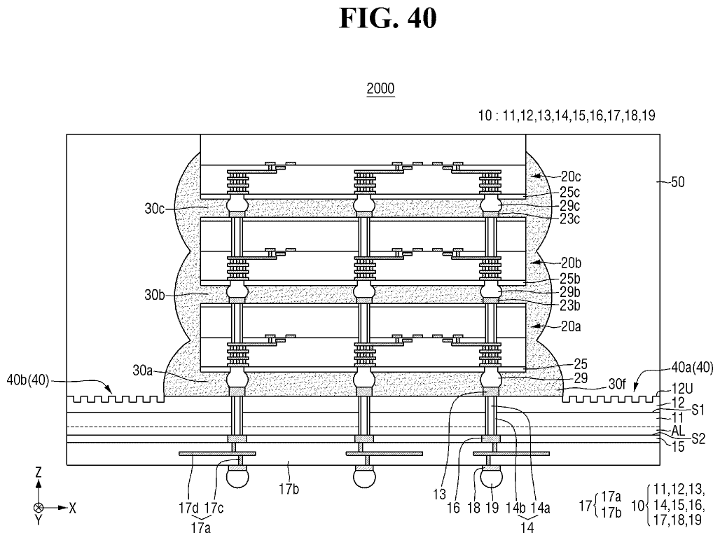

Referring to FIGS. 31 and 39, a core chip 20a having bumps 29 and an adhesive layer 30a is provided (S207), and a core chip 20a is stacked on the buffer die 10 by thermal compression bonding (S208). At this time, the core chip 20a may be stacked on the buffer die 10 by applying heat and pressure to an upper portion of the core chip 20a so that the backside pad 13 of the buffer die 10 and the bump 29 of the core chip 20a are in contact with each other. In this way, a plurality of core chips including adhesive layers may be vertically stacked on the buffer die 10. Then, referring to FIGS. 31 and 40, after the plurality of core chips 20a, 20b and 20c are all stacked on the buffer die 10, a mold layer 50 surrounding the upper surface of the buffer die 10 and the plurality of core chips 20a, 20b and 20c is formed (S209).

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a combination can in some cases be excised from the combination, and the combination may be directed to a subcombination or variation of a subcombination.

While the present disclosure has been particularly illustrated and described with reference to exemplary implementations thereof, it will be understood by those of ordinary skill in the art that various changes in form and detail may be made therein without departing from the spirit and scope of the present disclosure as defined by the following claims. The exemplary implementations should be considered in a descriptive sense only and not for purposes of limitation.

What is claimed is:

1. A semiconductor package comprising:
a buffer die including a semiconductor substrate and a passivation layer, wherein the semiconductor substrate includes a first surface and a second surface facing each other, and wherein the passivation layer is formed on the first surface;
a plurality of core chips stacked on the buffer die, wherein the plurality of core chips include a first core chip disposed at a lowermost end of the plurality of core chips;
an adhesive layer between the buffer die and the first core chip; and
a mold layer surrounding an upper surface of the buffer die and the plurality of core chips,
wherein an upper surface of the passivation layer has a plurality of recesses recessed inward from the upper surface of the passivation layer, and
wherein the plurality of recesses surround the first core chip and are offset from the first core chip horizontally.

2. The semiconductor package of claim 1,
wherein the plurality of recesses include a recess group extending in a first direction,
wherein the recess group includes first to (n)th recesses aligned in the first direction,
wherein the upper surface of the passivation layer has a plurality of protrusions,
wherein first to (n−1)th protrusions of the plurality of protrusions are disposed between the first to (n)th recesses, respectively, and
wherein n is an integer of 2 or more.

3. The semiconductor package of claim 2,
wherein the recess group includes a first edge and a second edge,
wherein the first edge and the second edge face each other in the first direction, and
wherein the first edge and the second edge satisfy ⅕≤B/A≤ 33/100, where a length from the first edge to the second edge is A, and a length of the recess in the first direction is B.

4. The semiconductor package of claim 3, wherein B is 0.5 μm or more and 10 μm or less.

5. The semiconductor package of claim 2, wherein upper surfaces of the first to (n−1)th protrusions are positioned on a same plane as the upper surface of the passivation layer.

6. The semiconductor package of claim 2,
wherein the first core chip includes a first edge and a second edge,
wherein the first edge and the second edge face each other in the first direction,
wherein the buffer die includes a third edge and a fourth edge,
wherein the third edge and the fourth edge face each other in the first direction, and
wherein the first edge and the third edge are disposed on a same side with respect to a center of the first core chip.

7. The semiconductor package of claim 6,
wherein the recess group includes a fifth edge and a sixth edge,
wherein the fifth edge and the sixth edge face each other in the first direction, and
wherein 3/20≤B/A≤1 is satisfied, where a length from the first edge to the third edge is A, and a length from the fifth edge to the sixth edge is B.

8. The semiconductor package of claim 7, wherein B is 30 μm or more and 250 μm or less.

9. The semiconductor package of claim 1, wherein 3/20≤B/A≤½ is satisfied, where a length of the passivation layer in a first direction is A and a length of the recess in the first direction is B.

10. The semiconductor package of claim 9, wherein B is 0.5 μm or more and 10 μm or less.

11. A semiconductor package comprising:
a package substrate;
an interposer on the package substrate;
a first semiconductor chip disposed in a first region of the interposer; and
a memory device disposed in a second region that is offset from the first region on the interposer,
wherein the memory device includes:
a buffer die including a semiconductor substrate and a passivation layer, wherein the semiconductor substrate includes a first surface and a second surface facing each other, and wherein the passivation layer is formed on the first surface;
a plurality of core chips stacked on the buffer die, wherein the plurality of core chips include a first core chip disposed at a lowermost end of the plurality of core chips;
an adhesive layer between the buffer die and the first core chip; and
a mold layer surrounding an upper surface of the buffer die and the plurality of core chips,
wherein an upper surface of the passivation layer has a plurality of recesses recessed inward from the upper surface of the passivation layer, and
wherein the plurality of recesses surround the first core chip and are offset from the first core chip horizontally.

12. The semiconductor package of claim 11,
wherein the passivation layer includes a first layer, a second layer, and a third layer,
wherein the first layer, the second layer, and the third layer are sequentially stacked on the first surface of the semiconductor substrate,
wherein the first layer and the third layer include silicon oxide (SiO₂), and
wherein the second layer includes silicon nitride (SiN).

13. The semiconductor package of claim 12, wherein the plurality of recesses are formed in the third layer, and the second layer is not exposed by the plurality of recesses.

14. The semiconductor package of claim 12, wherein the plurality of recesses are formed in the third layer, and at least a portion of the second layer is exposed by the plurality of recesses.

15. The semiconductor package of claim 11, wherein the memory device is a high bandwidth memory (HBM).

16. The semiconductor package of claim 11,
wherein the plurality of core chips include a second core chip,
wherein the second core chip is disposed on an uppermost end of the plurality of core chips, and
wherein an upper surface of the second core chip and an upper surface of the mold layer are disposed on the same plane.

17. A fabricating method of a semiconductor package, the fabricating method comprising:
providing a buffer die including a first semiconductor substrate and a through electrode, wherein the through electrode penetrates at least a portion of the buffer die in a vertical direction, and wherein the first semiconductor substrate has a first surface and a second surface facing each other;
forming a passivation layer on the first surface of the first semiconductor substrate;
forming a photoresist layer on the passivation layer;
disposing a first mask having a first pattern on the buffer die;
exposing the buffer die with the first mask;
forming, on the upper surface of the passivation layer, a plurality of recesses to recessed inward from an upper surface of the passivation layer by developing the buffer die;
removing at least a portion of the passivation layer by a chemical mechanical polishing (CMP) process;
forming the photoresist layer on the passivation layer again;
disposing a second mask having a second pattern on the buffer die;
exposing the buffer die again with the second mask;
forming a backside pad connected to the through electrode by developing the buffer die again;
providing a core chip including a second semiconductor substrate, an adhesive layer, and a bump, wherein the bump is formed on a lower portion of the core chip, wherein the second semiconductor substrate has a third surface and a fourth surface facing each other, wherein the lower portion of the core chip corresponds to the fourth surface, and wherein the adhesive layer covers the lower portion of the core chip and the bump;
stacking the core chip on the buffer die by performing thermal compression bonding between the buffer die and the core chip so that the backside pad of the buffer die and the bump of the core chip are in contact with each other; and
forming a mold layer surrounding the upper surface of the passivation layer and the core chip.

18. The fabricating method of claim 17, wherein the plurality of recesses are aligned with the first pattern in the vertical direction.

19. The fabricating method of claim 17, wherein the backside pad is aligned with the second pattern in the vertical direction.

20. The fabricating method of claim 17, wherein the plurality of recesses are formed to surround the core chip and are offset from the core chip horizontally.
